(19) United States
(12) Patent Application Publication
(10) Pub. No.: US 2013/0161740 A1
(43) Pub. Date: Jun. 27, 2013

(54) Lateral High-Voltage Transistor with Buried Resurf Layer and Associated Method for Manufacturing the Same

(71) Applicants: Donald R. Disney, Cupertino, CA (US); Ognjen Milic, San Jose, CA (US)

(72) Inventors: Donald R. Disney, Cupertino, CA (US); Ognjen Milic, San Jose, CA (US)

(21) Appl. No.: 13/332,862

(22) Filed: Dec. 21, 2011

(51) Int. Cl. H01L 29/78; H01L 21/336

(52) U.S. Cl. 257/339; 438/286; 257/E29.261; 257/E21.417

(57) ABSTRACT

A lateral high-voltage transistor comprising a semiconductor layer of a first conductivity type; a source region of a second conductivity type in the semiconductor layer; a drain region of the second conductivity type in the semiconductor layer; a first isolation layer atop the semiconductor layer between the source and the drain regions; a first well region of the second conductivity type surrounding the drain region; a gate positioned atop the first isolation layer adjacent to the source region; a spiral resistive field plate atop the first isolation layer spiraling between the drain region and the gate, wherein the spiral resistive field plate is coupled in series to the source and drain regions; and a buried layer of the first conductivity type in the first well region, wherein the buried layer is buried beneath a top surface of the first well region below the spiral resistive field plate.

### TECHNICAL FIELD

This disclosure relates generally to semiconductor devices, and particularly relates to lateral high-voltage transistors.

### BACKGROUND

Integrated circuits such as power supply circuits for industrial and consumer electronic devices usually comprise a high-voltage transistor at their output terminals. The high-voltage transistor used in such power management applications may be switched ON or OFF in response to control signals to convert a supply voltage into an output voltage which is suitable to power industrial and consumer electronic devices. In most high-voltage power management applications, the supply voltage may be quite high (e.g. as high as 1000V), thus, the high-voltage transistor should be capable to withstand such a high supply voltage. That is to say, the high-voltage transistor should have a high breakdown voltage in terms of the stability of a power supply circuit. In the meanwhile, the high-voltage transistor should better have a low on-resistance to improve the current handling performance of the high-voltage transistor and to increase the efficiency of power conversion of the power supply circuit.

Usually, the on-resistance of the high-voltage transistor can be decreased by increasing the doping concentration within a drift region between a drain region and a source region of the high-voltage transistor. However, increasing the doping concentration within the drift region may cause the drift region to become more difficult to be completely depleted, resulting in a decrease in breakdown voltage. Therefore, it is desired to provide a high-voltage transistor device having low on-resistance without decreasing the breakdown voltage.

### SUMMARY

In accomplishing the above and other objects, there has been provided, in accordance with an embodiment of the present disclosure, a lateral high-voltage transistor, comprising: a semiconductor layer of a first conductivity type; a source region of a second conductivity type opposite to the first conductivity type, wherein the source region is located in the semiconductor layer near a top surface of the semiconductor layer; a drain region of the second conductivity type, wherein the drain region is located in the semiconductor layer near the top surface of the semiconductor layer, and wherein the drain region is separated from the source region; a first isolation layer atop the semiconductor layer between the source region and the drain region; a first well region of the second conductivity type surrounding the drain region, wherein the first well region extends towards the source region and is separated from the source region; a gate positioned atop the first isolation layer adjacent to the source region; a spiral resistive field plate atop the first isolation layer spiraling between the drain region and the gate, wherein the spiral resistive field plate comprises a first end coupled to the source region and a second end coupled to the drain region; and a buried layer of the first conductivity type in the first well region, wherein the buried layer is buried beneath a top surface of the first well region below the spiral resistive field plate.

In addition, there has been provided, in accordance with an embodiment of the present disclosure, a method of forming a lateral high-voltage transistor comprising: providing a semiconductor layer of a first conductivity type; forming a first well region of a second conductivity type opposite to the first conductivity type in the semiconductor layer; forming a drain region of the second conductivity type in the first well region near a top surface of the first well region, and a source region of the second conductivity type in the semiconductor layer near a top surface of the semiconductor layer; forming a buried layer of the first conductivity type in the first well region beneath the top surface of the first well region; forming a first isolation layer atop the first well region and the semiconductor layer between the source region and the drain region; forming a gate atop the first isolation layer near the source region; and forming a spiral resistive field plate atop the first isolation layer between the drain region and the gate, wherein the spiral resistive field plate comprises a first end coupled to the source region and a second end coupled to the drain region.

### BRIEF DESCRIPTION OF THE DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates schematically a sectional view of a lateral high-voltage transistor 100 in accordance with an embodiment of the present invention.

FIG. 2 illustrates schematically a sectional view of a lateral high-voltage transistor 200 in accordance with another embodiment of the present invention.

FIG. 3 illustrates schematically a sectional view of a lateral high-voltage transistor 300 in accordance with another embodiment of the present invention.

FIG. 4 shows a flow chart illustrating a method of forming a high-voltage transistor in accordance with an embodiment of the present invention.

The use of the same reference label in different drawings indicates the same or like components or structures with substantially the same functions for the sake of simplicity.

### DETAILED DESCRIPTION

Various embodiments of the present invention will now be described. In the following description, some specific details, such as example circuits and example values for these circuit components, are included to provide a thorough understanding of the embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the terms “left,” right,” “in,” “out,” “front,” “back,” “up,” “down, “top,” “atop”, “bottom,” “over,” “under,” “above,” “below” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The term “coupled,” as used herein, is defined as directly or indirectly connected in an electrical or non-electrical manner. The terms “a,” “an,” and “the” includes plural reference, and the term “in” includes “in” and “on”. The phrase “in one embodiment,” as used herein does not necessarily refer to the same embodiment, although it may. The term “or” is an inclusive “or” operator, and is equivalent to the term “and/or” herein, unless the context clearly dictates otherwise. Those skilled in the art should understand that the meanings of the terms identified above do not necessarily limit the terms, but merely provide illustrative examples for the terms.

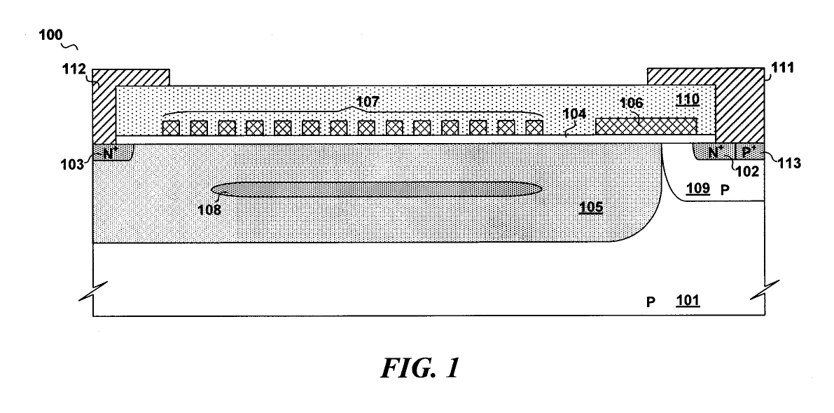

FIG. 1 illustrates schematically a sectional view of a lateral high-voltage transistor 100 in accordance with an embodiment of the present invention. The lateral high-voltage transistor 100 comprises a semiconductor layer 101 of a first conductivity type (e.g. P-type in FIG. 1); a source region 102 of a second conductivity type (e.g. N-type in FIG. 1) opposite to the first conductivity type, wherein the source region 102 is located in the semiconductor layer 101 near a top surface of the semiconductor layer 101, and wherein the source region 102 may have a heavy dopant concentration, for example, higher than 1×10¹⁹ cm⁻³; a drain region 103 of the second conductivity type (e.g. an N⁺ region in FIG. 1), wherein the drain region 103 is located in the semiconductor layer 101 near the top surface of the semiconductor layer 101, and wherein the drain region 103 is separated from the source region 102, and wherein the drain region 103 may have a heavy dopant concentration, for example, higher than 1×10¹⁹ cm⁻³; a first isolation layer 104 atop the semiconductor layer 101 between the source region 102 and the drain region 103; a first well region 105 of the second conductivity type surrounding the drain region 103, wherein the first well region 105 extends towards the source region 102 and is separated from the source region 102; a gate 106 positioned atop the first isolation layer 104 adjacent to the source region 102; a spiral resistive field plate 107 atop the first isolation layer 104 between the drain region 103 and the gate 106, wherein the spiral resistive field plate 107 comprises a first end coupled to the source region 102 and a second end coupled to the drain region 103; and a buried layer 108 of the first conductivity type in the first well region 105, wherein the buried layer 108 is buried beneath a top surface of the first well region 105 below the spiral resistive field plate 107.

In one embodiment, the first isolation layer 104 may comprise silicon dioxide. In other embodiment, the first isolation layer 104 may comprise other isolation materials that are compatible with other aspects of the device manufacturing process.

In one embodiment, the gate 106 may comprise doped poly-silicon. In other embodiment, the gate 106 may comprise other conductive materials (e.g., metals, other semiconductors, semi-metals, and/or combinations thereof) that are compatible with other aspects of the device manufacturing process. Thus, the term “poly-silicon” is intended to include such other materials and material combinations in addition to silicon.

In one embodiment, the spiral resistive field plate 107 may comprise a long and narrow resistor formed by medium to high resistivity polysilicon and arranged as a spiral between the drain region 103 and the gate 106. The width of each segment of the spiral resistive field plate 107 may be about 0.4 μm to 1.2 μm, and the space between each segment may be about 0.4 μm to 1.2 μm. In other embodiments, the spiral resistive field plate 107 may be implemented by any other conventional methods.

In accordance with the embodiment shown in FIG. 1, the spiral resistive field plate 107 may act as a large resistor coupled between the drain region 103 and the source region 102, allowing only a very small leakage current to flow from the drain region 103 to the source region 102 of the high-voltage transistor device 100 when the high-voltage transistor device is in OFF state and a high voltage is applied on the drain electrode 109. In addition, when a high voltage is applied on the drain electrode 109, the spiral resistive field plate 107 may help to establish a linear voltage distribution along the surface of the first well region 105 between the drain region 103 and the source region 102. The linear voltage distribution may provide a uniform electric field distribution in the first well region 105, alleviating the formation of high electric field locations in the first well region 105, improving the breakdown voltage of the high-voltage transistor device 100.

Further, in the embodiment shown in FIG. 1, the buried layer 108 may be viewed as a buried reduced surface field (RESURF) layer. The spiral resistive field plate 107 and the buried layer 108 may help to deplete a first portion of the first well region 105 located above the buried layer 108. And the buried layer 108 and the semiconductor layer 101 may help to deplete a second portion of the first well region 105 located below the buried layer 108 and above the semiconductor layer 101. In this way, charges in the first well region 105, the buried layer 108 and the semiconductor layer 101 are balanced such that these layers are mutually depleted, further increasing the breakdown voltage of the high-voltage transistor 100. In the meanwhile, the first well region 105 of the lateral high-voltage transistor 100 may have a much higher dopant concentration than would be possible without the spiral resistive field plate 107 and the buried layer 108, allowing the high-voltage transistor 100 to have a further reduced on-resistance without lowering the breakdown voltage.

Moreover, the spiral resistive field plate 107 may help to shield the high-voltage transistor 100 from the influence of mobile charge in overlying dielectric layers (such as passivation layers and package molding compound), enhancing the reliability of the high-voltage transistor 100.

In one embodiment, still referring to FIG. 1, the high-voltage transistor device 100 may further comprise a second well region 109 of the first conductivity type (e.g. a P-type body region in FIG. 1) surrounding the source region 102. The second well region 109 may be provided with higher dopant concentration than the semiconductor layer 101, thus increasing the threshold voltage of the high-voltage transistor device 100 and reducing a punch-through leakage between the first well region 105 and the source region 102.

In one embodiment, the lateral high-voltage transistor 100 may further comprise a first dielectric layer 110 covering the first isolation layer 104, the gate 106 and the spiral resistive field plate 107; a source electrode 111 coupled to the source region 102; a drain electrode 112 coupled to the drain region 103; and a gate electrode (not shown in FIG. 1) coupled to the gate 106.

In an exemplary embodiment, the first end of the spiral resistive field plate 107 may be coupled to the source region 102 via the source electrode 111, and the second end of the spiral resistive field plate 107 may be coupled to the drain region via the drain electrode 112.

In one embodiment, the lateral high-voltage transistor 100 may further comprise a body contact region 113 of the first conductivity type with a heavy dopant concentration (e.g. a P⁺ body contact region in FIG. 1) adjacent to the source region 102. The body contact region 113 may be connected to the source region 102 and coupled to the source electrode 111, as shown in FIG. 1. In other embodiments, the lateral high-voltage transistor 100 may further comprise a body electrode (not shown in FIG. 1) separated from the source electrode 111, wherein the body contact region 113 is separated from the source region 102 and is coupled to the body electrode instead of the source electrode 111, such that the source region 102 can assume a voltage higher than that of the body contact region 113 (i.e. the source region 102 can assume a voltage higher than that of the semiconductor layer 101).

In one embodiment, the first end of the spiral resistive field plate 107 may be coupled to the gate 106 or to the body contact region 113 instead of being coupled to the source region 102.

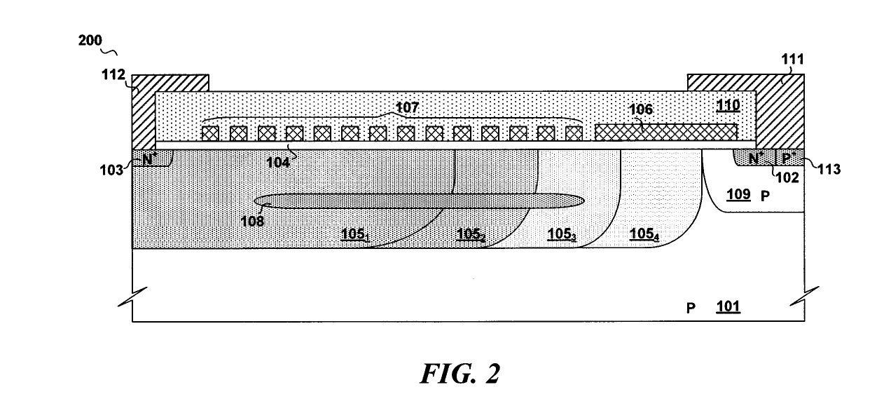

FIG. 2 illustrates schematically a sectional view of a lateral high-voltage transistor 200 in accordance with another embodiment of the present invention. Components or structures in the lateral high-voltage transistor 200 with substantially the same functions as those of the lateral high-voltage transistor 100 are identified by the same reference labels as used in the lateral high-voltage transistor 100 for the sake of simplicity. As illustrated in FIG. 2, the first well region 105 of the lateral high-voltage transistor 200 may comprise a plurality of second-conductivity-type dopant zones wherein each second-conductivity-type dopant zone has a different dopant concentration from the other second-conductivity-type dopant zones. In one embodiment, the plurality of second-conductivity-type dopant zones may have gradually lowering dopant concentrations in the direction from the dopant zone immediately surrounding the drain region 103 to the dopant zone farthest from the drain region 103. For example, the dopant zone closest to the drain region 103 may have a dopant concentration lighter than that of the drain region 103, the dopant zone furthest from the drain region may have a dopant concentration lighter than that of the dopant zone closer to the drain region 103. In this case, the lateral high-voltage transistor 200 may have a further decreased on-resistance without decreasing the breakdown voltage, because the first well region 105 is doped lighter near the source region 102, reducing the possibility of breakdown near the source region 102.

In the exemplary embodiment shown in FIG. 2, the well region 105 is illustrated as to comprise four second-conductivity-type dopant zones 105₁˜105₄, while the drain region 103 is heavy doped with a dopant concentration greater than 1*10¹⁹ cm⁻³, the second-conductivity-type dopant zone 105₁ immediately surrounding the drain region 103 is doped with a dopant concentration of about 4*10¹² cm⁻³, the second-conductivity-type dopant zones 105₂, 105₃ and 105₄ are respectively doped with dopant concentrations of about 3×10¹² cm⁻³, 2×10¹² cm⁻³ and 1×10¹² cm⁻³. It can be appreciated by those of ordinary skill in the art that the number of the second-conductivity-type dopant zones, the doping concentration of each second-conductivity-type dopant zone, and the width of each second-conductivity-type dopant zone may be modified as required to optimize the performance of the high-voltage transistor device 200.

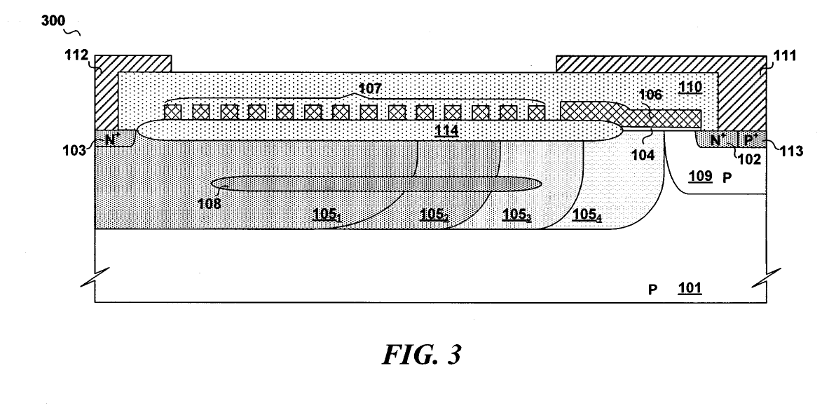

FIG. 3 illustrates schematically a sectional view of a lateral high-voltage transistor 300 in accordance with another embodiment of the present invention. Components or structures in the lateral high-voltage transistor 300 with substantially the same functions as those of the lateral high-voltage transistors 100 and 200 are identified by the same reference labels as used in the lateral high-voltage transistors 100 and 200 for the sake of simplicity. As illustrated in FIG. 3, the high-voltage transistor device 300 may further comprise a thick dielectric layer 114 (e.g. a thick field oxide layer) over a portion of the first well region 105 to laterally isolate the drain region 103 from the gate 106 and the source region 102, wherein the gate 106 may have a portion extending on top of the thick dielectric, layer 114, and wherein the spiral resistive field plate is atop the thick dielectric layer 114 instead of the first isolation layer 108. In one embodiment, the thick dielectric layer 114 may also comprise silicon dioxide.

The advantages of the various embodiments of the present invention are not confined to those described above. These and other advantages of the various embodiments of the present invention will become more apparent upon reading the whole detailed descriptions and studying the various figures of the drawings.

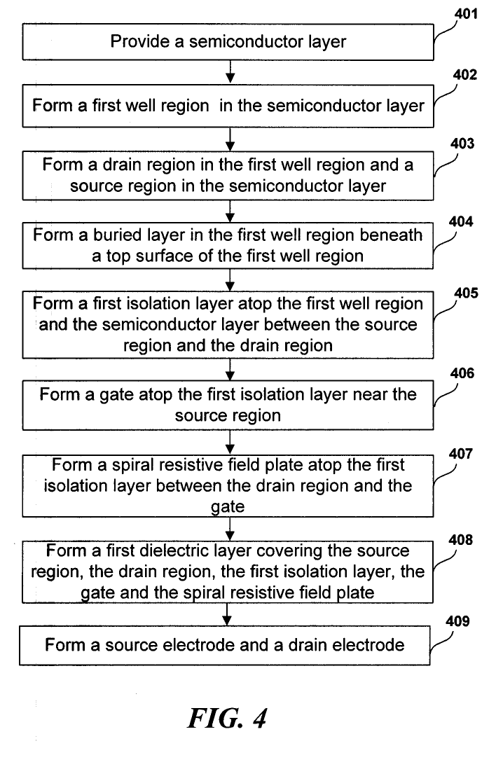

FIG. 4 shows a flow chart illustrating a method of forming a high-voltage transistor in accordance with an embodiment of the present invention. The method comprises: providing a semiconductor layer of a first conductivity type at step 401; forming a first well region of a second conductivity type opposite to the first conductivity type in the semiconductor layer at step 402; forming a drain region of the second conductivity type in the first well region near a top surface of the first well region and a source region of the second conductivity type in the semiconductor layer near a top surface of the semiconductor layer at step 403, wherein the source region and the drain region may have a heavy dopant concentration; forming a buried layer of the first conductivity type in the first well region beneath the top surface of the first well region at step 404; forming a first isolation layer atop the first well region and the semiconductor layer between the source region and the drain region at step 405; forming a gate atop the first isolation layer near the source region at step 406; and forming a spiral resistive field plate atop the first isolation layer between the drain region and the gate at step 407, wherein the spiral resistive field plate comprises a first end coupled to the source region and a second end coupled to the drain region.

In one embodiment, forming the first well region at step 402 may comprise forming a plurality of second-conductivity-type dopant zones, wherein each second-conductivity-type dopant zone has a different dopant concentration from the other second-conductivity-type dopant zones. In one embodiment, the plurality of second-conductivity-type dopant zones may have gradually lowering dopant concentrations in the direction from the dopant zone immediately surrounding the drain region to the dopant zone farthest from the drain region. In one embodiment, the plurality of second-conductivity-type dopant zones may be formed using one or two mask layers. For example, in one embodiment, a first mask layer comprising a plurality of openings having various sizes may be applied for forming the plurality of second-conductivity-type dopant zones so that during an ion implantation step, the mask openings having larger sizes may allow more dopants to enter the semiconductor layer compared to those having smaller sizes. Thus, areas of the semiconductor layer under the mask openings having larger sizes are doped more heavily than areas of the semiconductor layer under the mask openings having smaller sizes. In one embodiment, a single diffusion step (e.g. anneal in a furnace using high temperature) may further be used after the ion implantation step to smooth out the lateral doping profile, yet maintaining a graded lateral doping profile. In another embodiment, in addition to the first mask layer, a second mask layer having a single opening may further be used to introduce a background dopant concentration level that elevates the dopant concentrations of all of the second-conductivity-type dopant zones.

In one embodiment, in order to reduce processing steps and cost, the spiral resistive field plate may be formed using a same layer that is used to form the gate. For example, at the step 406, a lightly-doped or undoped layer of polysilicon may be formed on the first isolation layer, and then may be doped with a first dose of N-type and/or P-type impurities (e.g. boron with a dose in the range of 1×10¹⁴ cm⁻³ to 1×10¹⁵ cm⁻³) to obtain a desired sheet resistance (e.g. 1 to 10 kohms/square) for the spiral resistive field plate. Subsequently, the polysilicon layer may be patterned and etched to form the spiral resistive field plate and the gate, and the gate may then be doped with a second dose of higher concentration of N-type and/or P-type impurities, for example using the source/drain region implant.

In one embodiment, the method of forming the high-voltage transistor may further comprise forming a first dielectric layer covering the source region, the drain region, the first isolation layer, the gate and the spiral resistive field plate at step 408; forming a source electrode and a drain electrode atop the first dielectric layer at step 409, wherein the source electrode is coupled to the source region and the first end of the spiral resistive field plate, and wherein the drain electrode is coupled to the drain region and the second end of the spiral resistive field plate. In one embodiment, at the step 409, the method of forming the high-voltage transistor may further comprise forming a gate electrode atop the first dielectric layer, wherein the gate electrode is coupled to the gate.

In another embodiment, the method of forming the high-voltage transistor may further comprise forming a second well region of the first conductivity type surrounding the source region at the step 403.

In another embodiment, the method of forming the high-voltage transistor may further comprise forming a body contact region of the first conductivity type with a heavy dopant concentration next to the source region at the step 403, wherein the body contact region is coupled to the source electrode. In another embodiment, the method of forming the high-voltage transistor device may further comprise forming a body electrode, wherein the body contact region is coupled to the body electrode instead of the source electrode.

In still another embodiment, the method of forming the high-voltage transistor may further comprise forming a gate electrode coupled to the gate at the step 409, wherein the first end of the spiral resistive field plate is coupled to the gate electrode instead of the source electrode.

In still another embodiment, the method of forming the high-voltage transistor may further comprise forming a thick dielectric layer over a portion of the first well region to laterally isolate the drain region from the gate and the source region at the step 405, wherein the gate may have a portion extending on top of the thick dielectric layer, and wherein the spiral resistive field plate is atop the thick dielectric layer instead of the first isolation layer.

Methods and processes of forming a high-voltage transistor device described in various embodiments of the present invention are illustrative and not intended to be limiting. Well known manufacturing steps, processes, materials and dopants etc. are not described in detail to avoid obscuring aspects of the technology. Those skilled in the art should understand that the steps described in the embodiments shown may be implemented in different orders and are not limited to the embodiments described.

Although the present disclosure takes an N-channel high-voltage transistor for example to illustrate and explain the structures of a high-voltage transistor according to various embodiments of the present invention, but this is not intended to be limiting and persons of skill in the art will understand that the structures and principles taught herein also apply to P-channel high-voltage transistors and to other types of semiconductor materials and devices as well.

From the foregoing, it will be appreciated that specific embodiments of the technology have been described herein for purposes of illustration, but that various modifications may be made without deviating from the technology. Many of the elements of one embodiment may be combined with other embodiments in addition to or in lieu of the elements of the other embodiments. Accordingly, the technology is not limited except as by the appended claims.

I/We claim:

1. A lateral high-voltage transistor, comprising:
a semiconductor layer of a first conductivity type;
a source region of a second conductivity type opposite to the first conductivity type, wherein the source region is located in the semiconductor layer near a top surface of the semiconductor layer;
a drain region of the second conductivity type, wherein the drain region is located in the semiconductor layer near the top surface of the semiconductor layer, and wherein the drain region is separated from the source region;
a first isolation layer atop the semiconductor layer between the source region and the drain region;
a first well region of the second conductivity type surrounding the drain region, wherein the first well region extends towards the source region and is separated from the source region;
a gate positioned atop the first isolation layer adjacent to the source region;
a spiral resistive field plate atop the first isolation layer spiraling between the drain region and the gate, wherein the spiral resistive field plate comprises a first end coupled to the source region and a second end coupled to the drain region; and
a buried layer of the first conductivity type in the first well region, wherein the buried layer is buried beneath a top surface of the first well region below the spiral resistive field plate.

2. The lateral high-voltage transistor of claim 1, wherein a first portion of the first well region located above the buried layer is depleted by the spiral resistive field plate and the buried layer, and wherein a second portion of the first well region located below the buried layer and above the semiconductor layer is depleted by the buried layer and the semiconductor layer.

3. The lateral high-voltage transistor of claim 1, wherein the first well region comprises a plurality of second-conductivity-type dopant zones, and wherein each second-conductivity-type dopant zone has a different dopant concentration from the other second-conductivity-type dopant zones.

4. The lateral high-voltage transistor of claim 3, wherein the first well region comprises a plurality of second-conductivity-type dopant zones having gradually lowering dopant concentrations in the direction from the dopant zone immediately surrounding the drain region to the dopant zone farthest from the drain region.

5. The lateral high-voltage transistor of claim 1 further comprising a second well region of the first conductivity type surrounding the source region.

6. The lateral high-voltage transistor of claim 1 further comprising a body contact region of the first conductivity type adjacent to the source region, wherein the body contact region is coupled to the source region.

7. The lateral high-voltage transistor of claim 6, wherein the first end of the spiral resistive field plated is coupled to the body contact region instead of the source region.

8. The lateral high-voltage transistor of claim 1, wherein the first end of the spiral resistive field plate is coupled to the gate instead of being coupled to the source region.

9. The lateral high-voltage transistor of claim 1, further comprising:
a first dielectric layer covering the first isolation layer, the gate and the spiral resistive field plate;
a source electrode coupled to the source region;
a drain electrode coupled to the drain region; and
a gate electrode coupled to the gate.

10. The lateral high-voltage transistor of claim 1 further comprising a thick dielectric layer over a portion of the first well region to laterally isolate the drain region from the gate and the source region, wherein
the gate comprises a portion extending on top of the thick dielectric layer, and wherein
the spiral resistive field plate is atop the thick dielectric layer instead of the first isolation layer.

11. A method of forming a lateral high-voltage transistor comprising:
providing a semiconductor layer of a first conductivity type;
forming a first well region of a second conductivity type opposite to the first conductivity type in the semiconductor layer;
forming a drain region of the second conductivity type in the first well region near a top surface of the first well region, and a source region of the second conductivity type in the semiconductor layer near a top surface of the semiconductor layer;
forming a buried layer of the first conductivity type in the first well region beneath the top surface of the first well region;
forming a first isolation layer atop the first well region and the semiconductor layer between the source region and the drain region;
forming a gate atop the first isolation layer near the source region; and
forming a spiral resistive field plate atop the first isolation layer between the drain region and the gate, wherein the spiral resistive field plate comprises a first end coupled to the source region and a second end coupled to the drain region.

12. The method of claim 11, wherein forming the first well region comprises:
forming a plurality of second-conductivity-type dopant zones, wherein each second-conductivity-type dopant zone has a different dopant concentration from the other second-conductivity-type dopant zones.

13. The method of claim 11, wherein forming the first well region comprises:
forming a plurality of second-conductivity-type dopant zones, wherein the plurality of second-conductivity-type dopant zones have gradually lowering dopant concentrations in the direction from the dopant zone immediately surrounding the drain region to the dopant zone farthest from the drain region.

14. The method of claim 11 further comprising forming a second well region of the first conductivity type surrounding the source region.

15. The method of claim 11 further comprising forming a body contact region of the first conductivity type with a heavy dopant concentration next to the source region.

16. The method of claim 11 further comprising forming a thick dielectric layer over a portion of the first well region to laterally isolate the drain region from the gate and the source region, wherein the gate has a portion extending on top of the thick dielectric layer, and wherein the spiral resistive field plate is atop the thick dielectric layer instead of the first isolation layer.

17. The method of claim 11 further comprising:
forming a first dielectric layer covering the source region, the drain region, the first isolation layer, the gate and the spiral resistive field plate; and
forming a source electrode and a drain electrode atop the first dielectric layer, wherein the source electrode is coupled to the source region and the first end of the spiral resistive field plate, and wherein the drain electrode is coupled to the drain region and the second end of the spiral resistive field plate.

18. The method of claim 17 further comprising:
forming a gate electrode atop the first dielectric layer, wherein the gate electrode is coupled to the gate.
